(19) United States
(12) Patent Application Publication
(10) Pub. No.: US 2010/0073823 A1
(43) Pub. Date: Mar. 25, 2010

(54) PIEZOELECTRIC ACTUATOR, HEAD SLIDER AND MAGNETIC DISK DRIVE

(75) Inventors: Tsuyoshi Aoki, Kawasaki (JP); Kazuaki Kurihara, Kawasaki (JP); Shigeyoshi Umemiya, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki-shi (JP)

(21) Appl. No.: 12/560,901

(22) Filed: Sep. 16, 2009

(30) Foreign Application Priority Data
Sep. 24, 2008 (JP) 2008-243983

(51) Int. Cl. G11B 21/24; H01L 41/047

(52) U.S. Cl. 360/291.9; 310/366; G9B/21.028

(57) ABSTRACT

A piezoelectric actuator includes a piezoelectric body; a first and a second electrode for applying an electric field to the piezoelectric body in order to polarize the piezoelectric body in a first direction at an elevated temperature, at least one of the first and the second electrode including a material whose resistivity decreases with elevation of the temperature; and a third and a fourth electrode for applying an electric field to the piezoelectric body in a second direction across the first direction of the polarization of the piezoelectric body in order to actuate the piezoelectric body.

### CROSS-REFERENCE TO RELATED APPLICATION

This application is based upon and claims the benefit of priority of the prior Japanese Patent Application No. 2008-243983, filed on Sep. 24, 2008, the entire contents of which are incorporated herein by reference.

### FIELD

The embodiments discussed herein are related to a piezoelectric actuator.

### BACKGROUND

Thanks to the technological improvement in magnetic disk, magnetic head, signal processing and so forth, the recording data capacity of a magnetic disk drive (HDD: Hard Disk Drive) is being increased at high rates and the track pitch of the magnetic disk is being reduced. Under such circumstances, the distance between the head slider and the magnetic disk, that is, the flying height of the magnetic head from the surface of the magnetic disk, is being reduced. Accordingly, it is desired that the flying height be precisely and rapidly controlled.

A technique for precisely controlling the flying height of the magnetic head has been known. In this technique, the head slider has a piezoelectric actuator using the polarization of a piezoelectric body, and the distance between the magnetic head and the magnetic disk is controlled by the displacement of the piezoelectric actuator.

For a piezoelectric actuator including a piezoelectric body polarizing in a direction nonparallel to the direction of the piezoelectricity applied for driving, it is difficult to recover a polarization amount reduced once. The polarization amount of the piezoelectric body is reduced during the manufacturing process of the head slider or in use of the head slider. If the polarization amount of the piezoelectric body is reduced, the displacement of the piezoelectric actuator is undesirably reduced.

Related-art techniques are disclosed in Japanese Laid-open Patent Publication No. 2000-348321.

### SUMMARY

According to an aspect of the invention, a piezoelectric actuator includes a piezoelectric body; a first and a second electrode for applying an electric field to the piezoelectric body in order to polarize the piezoelectric body in a first direction at an elevated temperature, at least one of the first and the second electrode including a material whose resistivity decreases with elevation of the temperature; and a third and a fourth electrode for applying an electric field to the piezoelectric body in a second direction across the first direction of the polarization of the piezoelectric body in order to actuate the piezoelectric body.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a sectional view of a piezoelectric actuator according to an embodiment;

FIG. 2 is a sectional view of a state of the piezoelectric actuator in which the piezoelectric actuator is driven to deform;

FIG. 3 illustrates the result of a simulation for equipotential surfaces in a piezoelectric body 11 when a potential deference of 30 V is produced between the driving electrodes 13a and 13b of a piezoelectric actuator including polarization electrodes 12a and 12b made of a material having a resistance of 1 MΩ or more;

FIG. 4 illustrates the result of a simulation for equipotential surfaces in a piezoelectric body 11 when a potential deference of 30 V is produced between the driving electrodes 13a and 13b of a piezoelectric actuator including polarization electrodes 12a and 12b made of platinum (Pt);

FIG. 5 is a temperature-resistance plot of a polycrystalline SiC film formed by CVD;

FIG. 6 is a sectional view of a piezoelectric actuator according to another embodiment;

FIG. 7 illustrates the result of a simulation for equipotential surfaces in a piezoelectric body 11 when a potential deference of 30 V is produced between the driving electrodes 13a and 13b of a piezoelectric actuator including polarization electrodes 12a and 12b made of platinum (Pt);

FIG. 8 illustrates the result of a simulation for equipotential surfaces in a piezoelectric body 11 when a potential deference of 30 V is produced between the driving electrodes 13a and 13b of a piezoelectric actuator including polarization electrodes 12a and 12b made of platinum (Pt);

FIG. 9 is a sectional view of a piezoelectric actuator according to another embodiment;

FIG. 10 is a sectional view of a magnetic disk drive according to an embodiment;

FIG. 11 is a sectional view of a magnetic disk drive according to an embodiment;

FIGS. 12A and 12B are representations of a magnetic head support;

FIG. 13 is a schematic perspective view of the structure of a head slider according to an embodiment;

FIG. 14 is a schematic diagram illustrating the section of the head slider illustrated in FIG. 13 and a magnetic disk together;

FIG. 15 is a perspective view of a head slider according to an embodiment, illustrating only the electrodes of the piezoelectric actuator;

FIG. 16 is a flow chart of a control means for recovering the displacement of the piezoelectric actuator by increasing the polarization amount of the piezoelectric body; and

FIGS. 17A to 17I are representations of a process for manufacturing a head slider according to an embodiment.

### DESCRIPTION OF EMBODIMENTS

Embodiments of the present invention will now be described with reference to drawings. The same reference numerals used in the drawings designate the same parts.

—Piezoelectric Actuator—

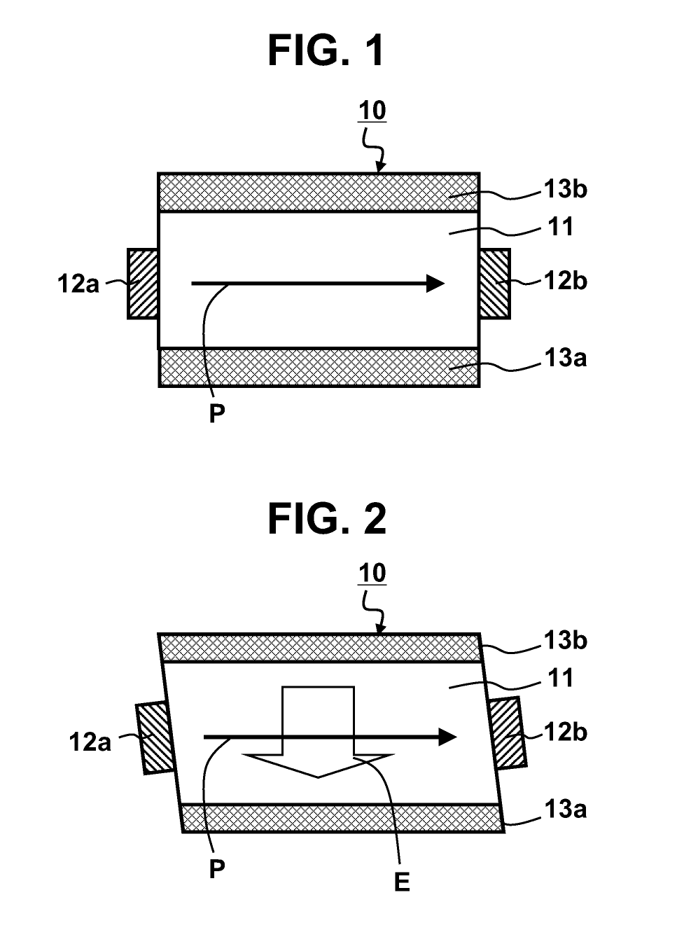

FIG. 1 is a sectional view of a piezoelectric actuator according to an embodiment. The piezoelectric actuator 10 is defined by a piezoelectric element including a piezoelectric body 11 made of a piezoelectric material, two polarization electrodes (first electrode, second electrode) 12a and 12b, and two driving electrodes (third electrode, fourth electrode) 13a and 13b. The piezoelectric body 11 is polarized along the direction (first direction) indicated by arrow P illustrated in FIG. 1, that is, in the direction from one polarization electrode 12a to the other polarization electrode 12b, by applying a potential to the two polarization electrodes 12a and 12b. The polarization amount of the piezoelectric body 11 is reduced during the manufacturing process of the piezoelectric actuator or in use of the piezoelectric actuator. In a piezoelectric actuator including a piezoelectric body polarizing in a direction nonparallel to the direction of the piezoelectricity applied for driving, the polarization electrodes 12a and 12b are provided for increasing the polarization amount of the piezoelectric body, for example, to recover a polarization reduced once.

FIG. 2 is a sectional view of the piezoelectric actuator deformed by being operated. Two driving electrodes 13a and 13b can apply an electric field to the piezoelectric body in the direction intersecting the polarization direction of the piezoelectric body 11. It is preferable that the driving electrodes 13a and 13b apply an electric field to the piezoelectric body in the direction perpendicular to the polarization direction of the piezoelectric body 11 (in the direction indicated by arrow E illustrated in FIG. 2) from the viewpoint of increasing the deformation of the piezoelectric actuator 10. The piezoelectric body 11 produces a d₁₅ mode displacement (shearing displacement) by applying a potential to the two driving electrodes 13a and 13b.

Piezoelectric materials used for the piezoelectric body 11 include materials having a high piezoelectric constant d₁₅, such as lead zirconate titanate PZT (Pb(Zr,Ti)O₃), and ferroelectric materials, such as lead lanthanum zirconate titanate PLZT((Pb,La)(Zr,Ti)O₃), potassium niobate (KNbO₃), and Nb-added PZT.

At least one, preferably both, of the polarization electrodes 12a and 12b is made of a material whose resistance varies with temperature, that is, a thermistor material. The thermistor material for the polarization electrodes 12a and 12b is not particularly limited. Thermistor materials include NTC (negative temperature coefficient) thermistor materials whose resistance is reduced as temperature increases, and CTR thermistor (critical temperature resistor) materials whose resistance is rapidly reduced at more than a certain temperature. The material of the polarization electrodes 12a and 12b can be appropriately selected from these thermistor materials. Examples of the NTC thermistor material include, for example, oxides of Mn, Co, Ni, Fe and other metals, silicon carbide (SiC), and barium titanate (BaTiO₃) containing Y or La. The CTR thermistor material may be vanadium oxide.

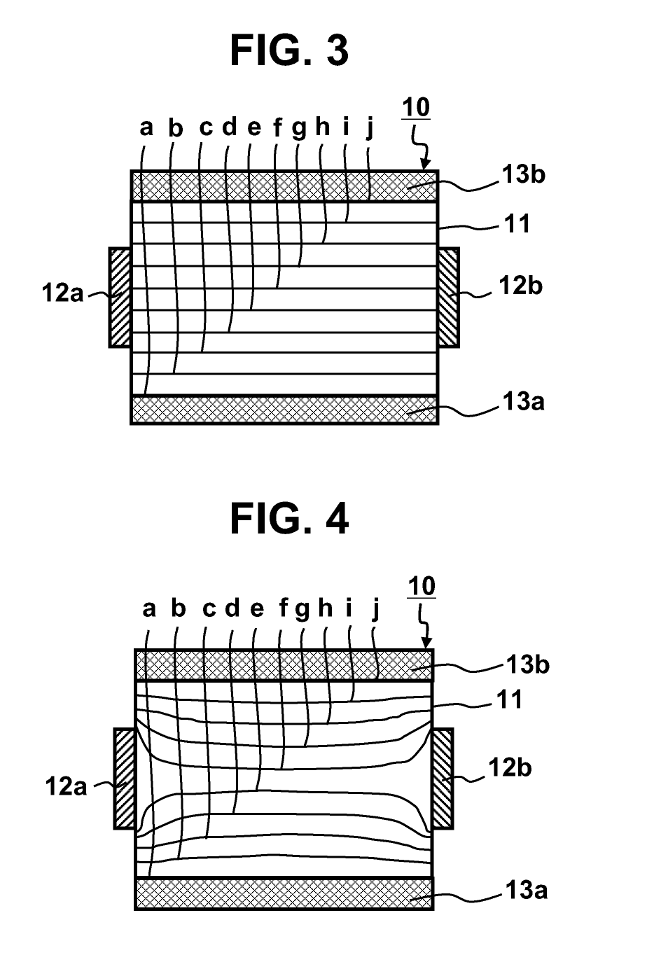

Preferably, the thermistor material used for the polarization electrodes 12a and 12b has a high resistance, for example, 1 MΩ or more, at a temperature at which a voltage is applied to the driving electrodes 13a and 13b. FIG. 3 illustrates the result of a simulation for equipotential surfaces in a piezoelectric body 11 when a potential deference of 30 V is produced between the driving electrodes 13a and 13b of a piezoelectric actuator including polarization electrodes 12a and 12b made of a material having a resistance of 1 MΩ or more and the piezoelectric body 11 made of PZT. Letter symbols a to j each represent an equipotential surface. a Represents 15 V; b represents 11.7 V; c represents 8.3 V; d represents 5.0 V; e represents 1.7 V; f represents −1.7 V; g represents −5.0 V; h represents −8.3 V; I represents −11.7 V; and j represents −15 V. The same representations of the letter symbols apply to FIGS. 4, 7 and 8 described later. FIG. 4 illustrates the result of a simulation for equipotential surfaces in a piezoelectric body 11 when a potential deference of 30 V is produced between the driving electrodes 13a and 13b of a piezoelectric actuator including polarization electrodes 12a and 12b made of electroconductive platinum (Pt) and the piezoelectric body 11 made of PZT. The piezoelectric body 11 has a width of 2 μm in the direction from the electrode 13a to the electrode 13b, a width of 3 μm in the direction from the electrode 12a to the electrode 12b, and a depth of 400 μm in the direction perpendicular to the sheet of the figure. The polarization electrodes 12a and 12b have a width of 1 μm in the direction from the electrode 13a to the electrode 13b.

When the polarization electrodes 12a and 12b are electrically isolated, as illustrated in FIG. 3, the electric field applied to the piezoelectric body 11 from the driving electrodes 13a and 13b is superior in straightness from one electrode 13a to the other electrode 13b. More specifically, lines of electric force (not illustrated) perpendicular to the equipotential surfaces run straight from the electrode 13a to the electrode 13b. Accordingly, the rate of the displacement of the piezoelectric actuator 10 to the potential difference produced between the driving electrodes 13a and 13b is large. On the other hand, when the polarization electrodes 12a and 12b are electrically conductive, as illustrated in FIG. 4, the electric field applied to the piezoelectric body 11 from the driving electrodes 13a and 13b is inferior in straightness from one electrode 13a to the other electrode 13b. The degradation of the straightness of the electric field is based on the electromagnetic law. Equipotential surfaces are produced at the surfaces of the polarization electrodes 12a and 12b by placing the electroconductive polarization electrodes 12a and 12b in an electric field, and the electric field, which is a potential gradient, is reduced around the equipotential surfaces. Due to the degradation of the straightness of the electric field, the rate of the displacement of the piezoelectric actuator 10 to the potential difference between the driving electrodes 13a and 13b is smaller than that of a piezoelectric actuator having electrically isolated polarization electrodes.

In addition, the thermistor material used for the polarization electrodes 12a and 12b preferably has a low resistance, for example, 1000Ω or less, at temperatures at which voltage is not applied to the driving electrodes 13a and 13b. This is because it is easy to apply a voltage that can polarize the piezoelectric body 11.

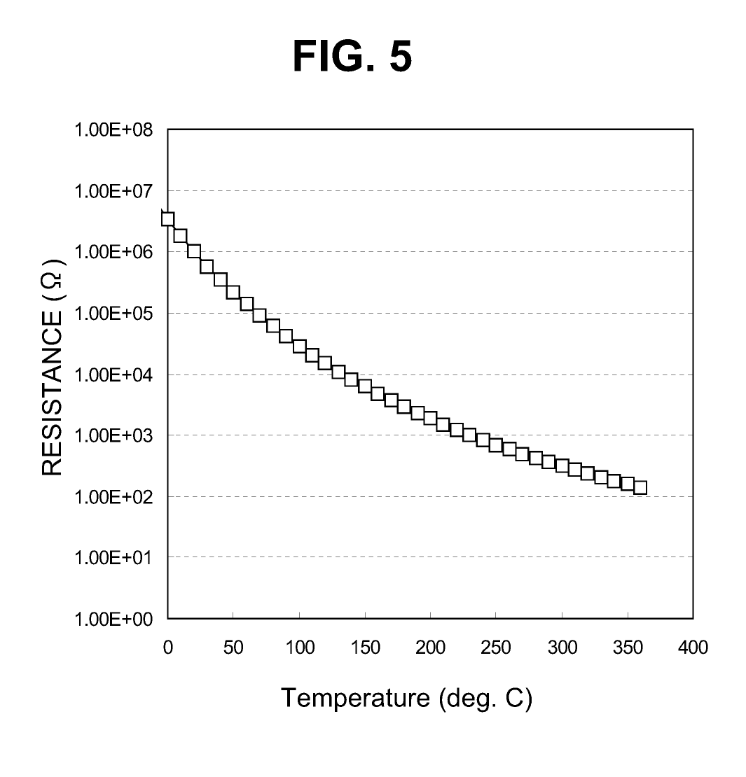

Among the materials satisfying the preferred resistance is silicon carbide (SiC). FIG. 5 is a plot of the temperature-resistance characteristics of a polycrystalline SiC film formed by CVD. The temperature-resistance characteristics of a thermistor are generally expressed by the following equation (1).

$$B = \frac{ln ( R \text{/} {R}_{0} )}{1 \text{/} T - 1 \text{/} {T}_{0}} \qquad Equation ( 1 )$$

In the equation, B represents the thermistor constant (B constant) (K), R represents resistance (Ω), T represents temperature (K), and T₀ and R₀ represent any reference temperature (K) and a resistance (Ω) at the reference temperature, respectively.

A polycrystalline SiC film formed by CVD may have a B constant of 4845 K. If the polycrystalline SiC film is designed so as to have a resistance of 1 MΩ at room temperature (20° C.), the temperature-resistance plot as illustrated in FIG. 5 is obtained from the above equation (1). The resistance is reduced by heating the SiC film. For example, the SiC film has a resistance of about 1000Ω at 220° C., and thus illustrates electroconductivity.

For example, PZT has a Curie temperature of 280 to 300° C. The Curie temperature is a temperature at which the polarization state of a ferroelectric material becomes random (paraelectric). When the piezoelectric body 11 is made of PZT and the polarization electrodes 12a and 12b are made of the above-described SiC, an electric field can be applied to the piezoelectric body 11 to increase the polarization amount by applying a potential difference between the polarization electrodes 12a and 12b at a temperature lower than the Curie temperature of the piezoelectric body 11 and at which the polarization electrodes 12a and 12b are heated to be electrically conductive, for example, at a temperature of 220 to 250° C. The piezoelectric body can be more easily polarized at temperatures close to the Curie temperature of the piezoelectric body than, for example, at room temperature because thermal fluctuations of electrons and electric dipoles are more increased around the Curie temperature.

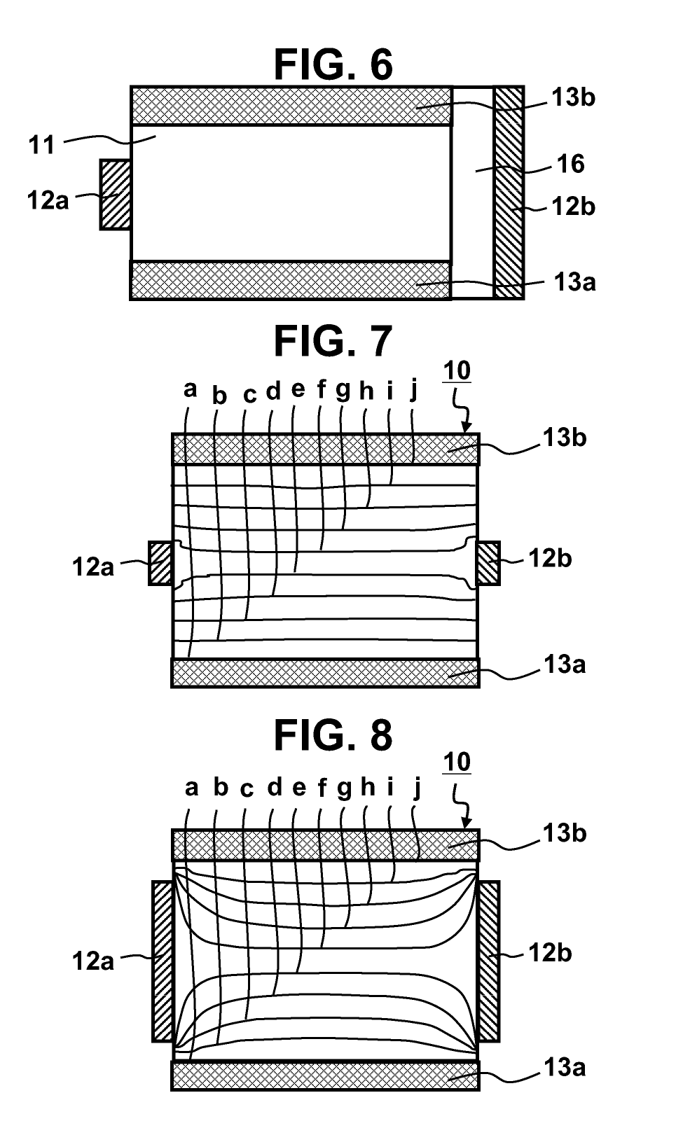

FIG. 6 is a sectional view of a piezoelectric actuator according to another embodiment. The same parts as described in the foregoing embodiment are not described. The piezoelectric actuator illustrated in FIG. 6 has an insulating layer 16 between the driving electrodes 13a and 13b and the polarization electrode 12b. The material of the insulating layer 16 is not particularly limited as long as it is electrically insulative. For example, it may be a piezoelectric material like the material used for the piezoelectric body 11, or a material not having piezoelectricity or ferroelectricity, such as alumina. For the case in which the driving electrodes 13a and 13b are thus separated from the polarization electrode 12b by the insulating layer 16, the material of the polarization electrode 12b can be appropriately selected from among electroconductive metals generally used as electrode material (for example, Pt, Ir, and Cu), electroconductive oxides (for example, indium tin oxide (ITO), SrRuOs and RuO₂), and electroconductive nitrides (for example, TiN and TiAlN). Since the electrode 12b is apart from the piezoelectric body 11, the straightness of the electric field from one driving electrode 13a to the other 13b is not easily degraded even if the polarization electrode 12b is electrically conductive when an electric field is applied to the piezoelectric body 11 using the driving electrodes 13a and 13b. Thus, the electrode 12b does not easily affect the operation of the piezoelectric actuator.

FIGS. 7 and 8 illustrate the result of a simulation for equipotential surfaces in a piezoelectric body 11 when a potential deference of 30 V is produced between the driving electrodes 13a and 13b of a piezoelectric actuator including polarization electrodes 12a and 12b made of electroconductive platinum (Pt) and the piezoelectric body 11 made of PZT. The same parts as described in the foregoing embodiments are not described. The width of the polarization electrodes 12a and 12b in the direction from one electrode 13a to the other electrode 13b is 0.4 μm for the piezoelectric actuator illustrated in FIG. 7, and is 1.6 μm for the piezoelectric actuator illustrated in FIG. 8. FIGS. 3, 7 and 8 illustrate that the straightness of the electric field applied to the piezoelectric body 11 from the driving electrodes 13a and 13b is enhanced as the width of the polarization electrode is reduced. In the piezoelectric actuator of the present invention, width of the polarization electrodes (first electrode and second electrode) in the direction from one driving electrode to the other (from third electrode to fourth electrode) is not particularly limited. When the polarization electrodes are not electrically isolated sufficiently at temperatures at which the piezoelectric actuator operates, however, the width of the polarization electrodes is preferably 50% or less of the width of the piezoelectric body in the direction from one driving electrode to the other from the viewpoint of enhancing the straightness of the electric field applied between the driving electrodes. In order to apply an electric field for increasing the polarization amount between the polarization electrodes, the width of the polarization electrodes in the direction from one driving electrode to the other is preferably 10% or more of the width of the piezoelectric body in the direction from one driving electrode to the other.

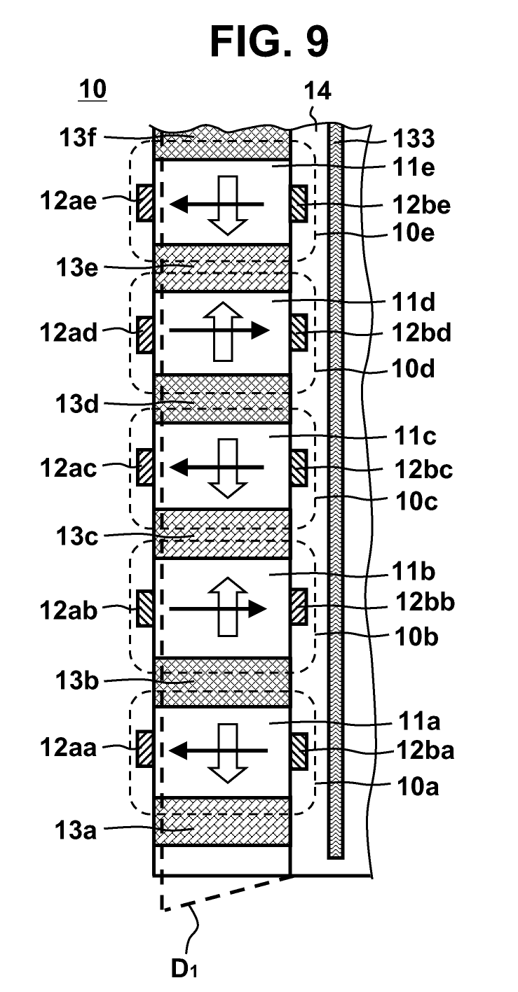

FIG. 9 is a sectional view of a piezoelectric actuator according to another embodiment. The piezoelectric actuator 10 includes a plurality of piezoelectric elements 10a, 10b, 10c, 10d and 10e that are disposed on a substrate 14.

The piezoelectric element 10a includes a piezoelectric body 11a made of a piezoelectric material, two polarization electrodes 12aa and 12ba, and two driving electrodes 13a and 13b. The piezoelectric element 10b includes a piezoelectric body 11b made of a piezoelectric material, two polarization electrodes 12ab and 12bb, and two driving electrodes 13b and 13c. The piezoelectric element 10c includes a piezoelectric body 11c made of a piezoelectric material, two polarization electrodes 12ac and 12bc, and two driving electrodes 13c and 13d. The piezoelectric element 10d includes a piezoelectric body 11d made of a piezoelectric material, two polarization electrodes 12ad and 12bd, and two driving electrodes 13d and 13e. The piezoelectric element 10e includes a piezoelectric body 11e made of a piezoelectric material, two polarization electrodes 12ae and 12be, and two driving electrodes 13e and 13f. Another piezoelectric element (not illustrated) may be provided opposite the piezoelectric element 10d beyond the piezoelectric element 10e. For example, the piezoelectric actuator 10 may further include another piezoelectric body disposed opposite to the piezoelectric body 11e with the driving electrode 13f therebetween, and two polarization electrodes separated by that another piezoelectric body and at least one of which has a resistance varying depending on temperature, and another driving electrode disposed opposite the driving electrode 13f with that another piezoelectric body therebetween. The piezoelectric elements 10a, 10b, 10c, 10d and 10e are aligned in a line in such a manner that their respective polarization electrodes 12ba, 12bb, 12bc, 12bd and 12be are in contact with the substrate 14. The substrate 14 contains a heater 133 for varying the temperature of the polarization electrodes 12aa to 12ae and 12ba to 12be. The heater 133 includes a thin layer pattern made of, for example, nickel chromium (NiCr) or tungsten (W). The resistance of the polarization electrodes 12aa to 12ae and 12ba to 12be can be varied by controlling the current flowing to the heater 133.

When an electric field is applied to the polarization electrodes, a voltage is applied so that the polarization directions of every two adjacent piezoelectric elements are opposite to each other in a state where the temperatures of the piezoelectric elements 10a to 10e are adjusted, as appropriate, with the heater 133 so that the polarization electrodes become electrically conductive. For example, when an electric field is applied in the direction from the electrode 12ba to the electrode 12aa in the piezoelectric element 10a, the electric field applied in the piezoelectric element 10b is in the direction from the electrode 12ab to the electrode 12bb, the electric field applied in the piezoelectric element 10c is in the direction from the electrode 12bc to the electrode 12ac, the electric field applied in the piezoelectric element 10d is in the direction from the electrode 12ad to the electrode 12bd, and the electric field applied in the piezoelectric element 10e is in the direction from the electrode 12be to the electrode 12ae. The piezoelectric bodies 11a to 11e are polarized by these electric fields in the same directions as the directions of the respective electric fields applied thereto.

Each two adjacent piezoelectric elements share a driving electrode. For example, the piezoelectric elements 10a and 10b share the driving electrode 13b, the piezoelectric elements 10b and 10c share the driving electrode 13c, the piezoelectric elements 10c and 10d share the driving electrode 13d, and the piezoelectric elements 10d and 10e share the driving electrode 13e. If a potential is applied so that the potentials of the driving electrodes 13a, 13c and 13e become lower than those of the driving electrodes 13b, 13d and 13f in a state where the temperatures of the piezoelectric elements 10a to 10b are adjusted, as appropriate, with the heater 133 so that the polarization electrodes become electrically isolated when the piezoelectric bodies 11a to 11e are polarized in the above-described directions, the piezoelectric elements 10a to 10e each produce a displacement (sharing displacement) in the d₁₅ mode using the surface of the substrate 14 as the fulcrum. The piezoelectric actuator in which a plurality of piezoelectric elements are arranged in an array with one of each pair of polarization electrodes in contact with the substrate, as described above, has a higher power than a piezoelectric actuator defined by a single piezoelectric element.

The piezoelectric actuators of the above-described embodiments can be manufactured any process without particular limitation. Each piezoelectric actuator of the above-described embodiment can be manufactured by a known thin-film forming process including a deposition technique applied to manufacture of integrated circuits, such as sputtering, a patterning technique using photolithography or etching, and a polishing technique, such as mechanical processing or abrasive machining.

Although the piezoelectric actuator can be applied to any use without particular limitation, it may be provided in, for example, a head slider of a magnetic disk drive. A head slider including the above-described piezoelectric actuator and a magnetic disk drive including the head slider will now be described.

—Magnetic Disk Drive—

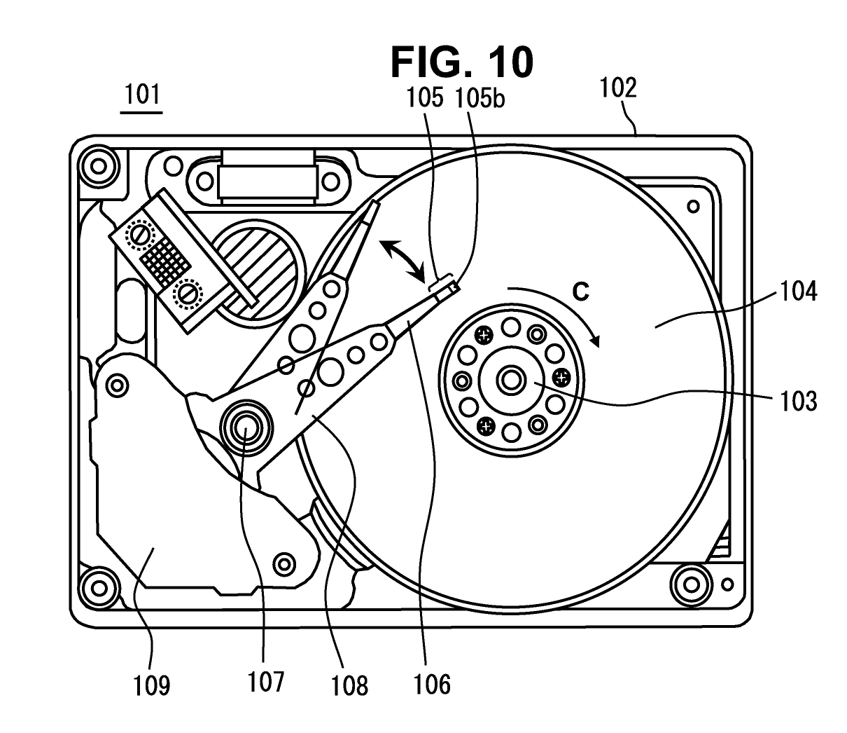

The magnetic disk drive 101 illustrated in FIG. 10 includes a housing 102 as illustrated in the figure as the exterior. In the housing 102 are disposed a magnetic disk 104 mounted on a rotation shaft 103 for rotation in the direction of arrow C, and a head slider 105 including a magnetic head 105b writing information to the magnetic disk 104 and reading the information from the magnetic disk. In the housing 102, also, are disposed a suspension 106 holding the head slider 105, a carriage arm 108 moving on an arm shaft 107 so as to move the suspension 106 along the surface of the magnetic disk 104, and an electromagnetic actuator 109 driving the carriage arm 108. For reading or writing information, the electromagnetic actuator 109 drives the carriage arm 108 to move the magnetic head 105b to a desired track on the magnetic disk (not illustrated). The housing 102 is closed with a cover (not illustrated). Thus, the above components are accommodated in an internal space defined by the housing 102 and the cover.

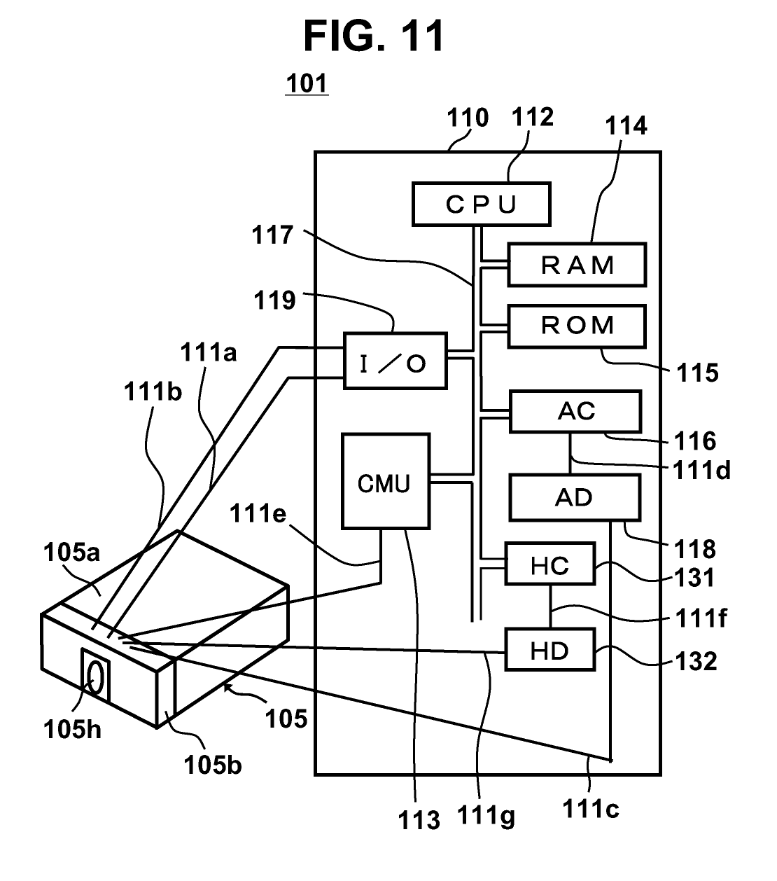

The magnetic disk drive 1 further includes a control circuit unit 110 controlling the operation of the magnetic disk drive 101, as illustrated in FIG. 11. The control circuit unit 110 is mounted, for example, on a control board (not illustrated) disposed within the housing 102. As illustrated in FIG. 11, the control circuit unit 110 includes a CPU (Central Processing Unit) 112, a (RAM (Random Access Memory) 114 in which data or the like to be processed by the CPU 112 are temporarily stored, a ROM (Read Only Memory) 115 in which a control program or the like is stored, an input/output circuit 119 for inputting and outputting signals for recording information (writing operation) and reproducing information (reading operation) into or from the magnetic head 105b, an actuator controller (AC) 116 controlling the piezoelectric actuator (not illustrated) disposed on the head slider 105, a bus 117 transmitting signals between these circuits, an actuator driver (AD) 118 applying a voltage to the actuator (not illustrated) according to a signal from the actuator controller 116, and a capacitance measuring unit (CMU) 113 for measuring the capacitance of the piezoelectric body (not illustrated) disposed in the piezoelectric actuator (not illustrated). If a heater (not illustrated) heating the piezoelectric actuator (not illustrated) is provided in the head slider 105, a heater driver (HD) 132 driving the heater (not illustrated) in the head slider 105 and a heater controller (HC) 131 controlling the heater driver 132 may be provided.

The input/output circuit 119 in the control circuit unit 110 is connected to the magnetic head 105b through wires 111a and 111b, as illustrated in FIG. 11. The actuator driver 118 is connected to the driving electrodes (not illustrated) and the polarization electrodes (not illustrated) of the piezoelectric actuator through wires 111c. The actuator controller 116 is connected to the actuator driver 118 through a wire 111d. The capacitance measuring unit 113 is connected to the driving electrodes (not illustrated) and the polarization electrodes (not illustrated) of the piezoelectric actuator through wires 111e. The heater controller 131 is connected to the heater driver 132 through a wire 111f. The heater driver 132 is connected to the heater (not illustrated) disposed in the head slider 105 (not illustrated) through a wire 111g. The head slider 105 will be described in detail later.

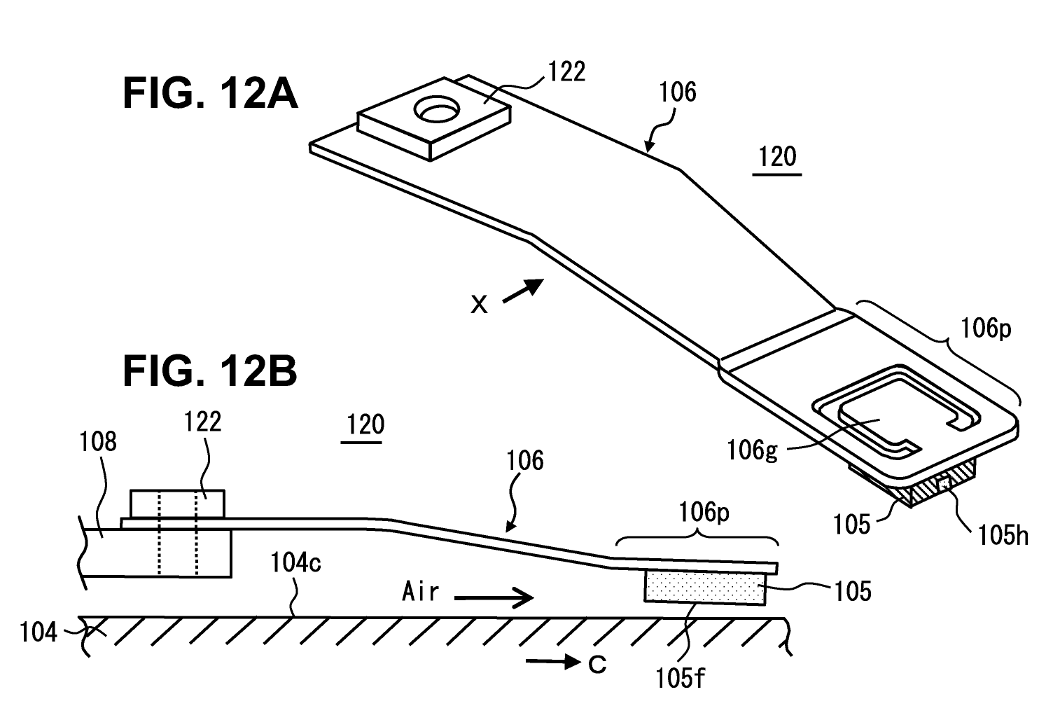

FIGS. 12A and 12B illustrate magnetic head supports. As illustrated in FIGS. 12 and 12B, the magnetic head support 120 generally refers to a structure including a suspension 106 having a base plate 122, a head slider 105 and others. The state before attaching the base plate 122 and the head slider 105, that is, the simple suspension 106, may be called magnetic head support. The structure including a suspension 106 having either a base plate 122 or a head slider 105 may also be called magnetic head support 120. The suspension 106 is, for example, a 20 μm thick sheet member made of stainless steel. The base plate 122 is joined to one end of the suspension 106 at the carriage arm 108 side, and the head slider 105 is joined to the other end (tip 106p). More specifically, for example, the head slider 105 is secured to a gimbal 106g disposed at the tip 106p of the suspension 106. The head slider 105 opposes the magnetic disk surface 104C. The magnetic head support may be referred to as HGA (Head Gimbal Assembly).

FIG. 12A is a perspective view of the magnetic head support, and FIG. 12B is a side view of the magnetic head support (viewed in the X direction illustrated in FIG. 12A).

As illustrated in FIG. 12B, an air flow in the direction indicated by arrow Air is produced by rotating the magnetic disk in the direction indicated by arrow C, and air flows into the gap under the flying surface (surface opposing the magnetic disk) 105f of the head slider. The head slider 105 receives a buoyancy generated by this air flow, and flies from the surface 104c of the magnetic disk 104.

—Head Slider—

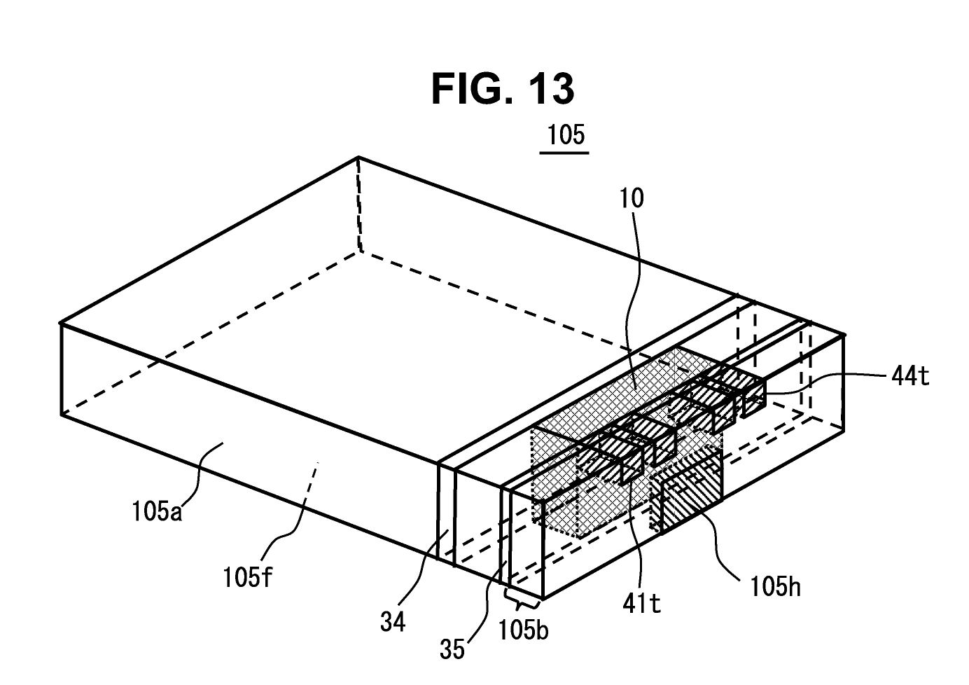

FIG. 13 is a schematic perspective view of the structure of the head slider 105. As illustrated in FIG. 13, the piezoelectric actuator 10 is disposed at an end of a slider substrate 105a. A magnetic head 105b is disposed opposite the slider substrate 105a with the piezoelectric actuator 10 therebetween. The magnetic head 105b includes an element portion 105h. The element portion 105h has, for example, a writing magnetic pole from which a magnetic field is applied to the magnetic disk and a reading sensor reading magnetic information of the magnetic disk, on the flying surface 105f side. The element portion 105h has a conventional structure that is not directly involved in the present invention, and the description of the element portion will be omitted. The magnetic head 105b includes external terminals 41t, 42t, 43t and 44t through which, for example, a voltage is applied to the piezoelectric bodies (not illustrated) of the piezoelectric actuator 10. The slider substrate 105a is made of a ceramic, such as AlTiC (Al₂O₃—TiC). AlTiC is one of ceramics, and is, more specifically, a fired product of alumina (Al₂O₃) and titanium carbide (TiC).

An insulating layer 34 is disposed between the slider substrate 105a and the piezoelectric actuator 10 to electrically isolate the piezoelectric actuator 10 from the slider substrate 105a. The insulating layer 34 is, for example, a 500 nm thick film made of an insulating material, and is formed at an end of the slider substrate 105a as illustrated in FIG. 13. Materials used for the insulating layer 34 include, for example, alumina (Al₂O₃) and titanium oxide (TiO₂). By providing such an insulating layer 34, the slider substrate 105a can be completely isolated from the electrodes of the piezoelectric actuator 10 to prevent noises of the piezoelectric actuator 10 from leaking to the slider substrate 105a.

Also, another insulating layer 35 is provided between the piezoelectric actuator 10 and the magnetic head 105b to electrically isolate the piezoelectric actuator 10 from the magnetic head 105b. The insulating layer 35 is, for example, a 500 nm thick film made of an insulating material. Materials used for the insulating layer 35 include, for example, alumina (Al₂O₃) and titanium oxide (TiO₂).

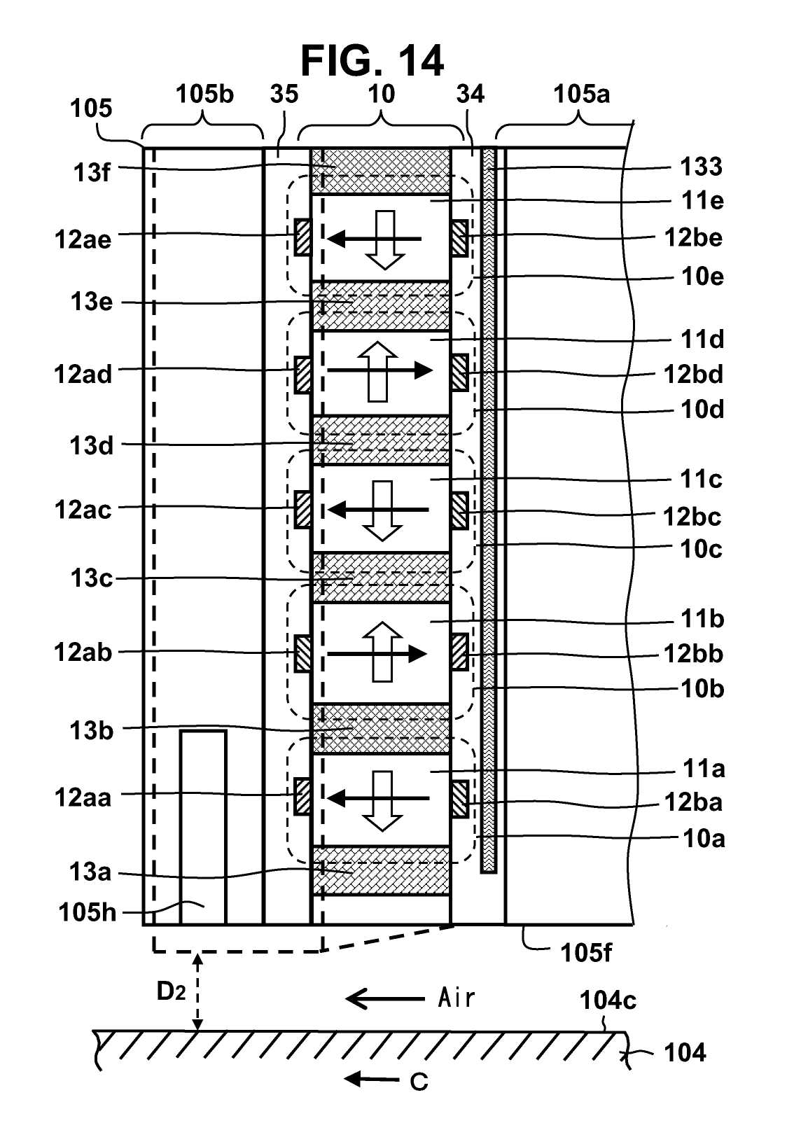

FIG. 14 is a schematic diagram illustrating the section of the head slider illustrated in FIG. 13 with the magnetic disk together. The section of the head slider illustrated in FIG. 14 is taken across the slider substrate 105a, the piezoelectric actuator 10 and the element portion 105h of the magnetic head.

The piezoelectric actuator 10 includes a plurality of piezoelectric elements 10a, 10b, 10c, 10d and 10e, and is disposed on the slider substrate 105a with the insulating layer 34 therebetween. The magnetic head 105b is disposed opposite the slider substrate 105a with the piezoelectric actuator 10 and the insulating layer 35 therebetween. The element portion 105h of the magnetic head is normally exposed at the flying surface 105f of the head slider 105b. In a memory device, the piezoelectric actuator 10 controls the distance (so-called flying height) D2 between the surface 104c of the magnetic disk 104 and the element portion 105h of the magnetic head. The piezoelectric actuator 10 has the same structure and arrangement as the piezoelectric actuator described with reference to FIG. 9.

The polarization amount of the piezoelectric bodies 11a to 11e is reduced during the manufacturing process of the piezoelectric actuator or in use of the piezoelectric actuator. In a piezoelectric actuator including piezoelectric bodies polarizing in a direction nonparallel to the direction of the piezoelectricity applied for driving, polarization electrodes 12aa to 12ae and 12ba to 12be are provided for increasing the polarization amount of the piezoelectric bodies to recover a polarization reduced once.

As with the piezoelectric actuator described with reference to FIG. 9, when an electric field is applied between the polarization electrodes 12aa, 12ab, 12ac, 12ad and 12ae and the polarization electrodes 12ba, 12bb, 12bc, 12bd and 12be, a voltage is applied so that the polarization directions of every two adjacent piezoelectric elements are opposite to each other at a temperature at which the polarization electrodes become electrically conductive. Every two adjacent piezoelectric elements share the corresponding one of the driving electrodes 13a to 13f as in the piezoelectric actuator as described with reference to FIG. 9.

If a voltage is applied so that the potentials of the driving electrodes 13a, 13c and 13e are lower than those of the driving electrodes 13b, 13d and 13f at a temperature at which the polarization electrodes becomes electrically isolated when the piezoelectric bodies 11a to 11e are polarized in the directions as described in the description of the piezoelectric actuator illustrated in FIG. 9, the piezoelectric elements 10a to 10e each produce a displacement (sharing displacement) in the d₁₅ mode using the insulating layer 34 disposed at an end of the slider substrate 105a as the fulcrum. In this instance, the polarization electrodes are electrically isolated as described with reference to FIG. 3, the electric fields applied from the driving electrodes to the respective piezoelectric bodies exhibit superior straightness. Accordingly, the rate of the displacement of the piezoelectric actuator 10 to the potential difference produced between each two driving electrodes separated by the piezoelectric body is large. The flying height D2 is controlled by controlling the displacement of each of the piezoelectric elements 10a to 10e.

The length of the piezoelectric bodies 11a to 11e in the direction from the electrode 13a to the electrode 13b is, for example, 2 μm, and that in the direction from the electrode 12aa to the electrode 12ba is, for example, 3 μm. The lengths of the driving electrodes 13a to 13f in the direction from the electrode 13a toward the electrode 13b are each 1 μm, and those in the direction from the electrode 12aa to the electrode 12ba are each 3 μm. The lengths of the polarization electrodes 12aa to 12ae and 12ba to 12be in the direction from the electrode 13a toward the electrode 13b are each 1 μm, and those in the direction from the electrode 12aa toward the electrode 12ba are each 0.2 μm. The lengths of the piezoelectric bodies 11a to 11e, the driving electrodes 13a to 13f, and the polarization electrodes 12aa to 12ae and 12ba to 12be in the depth direction of FIG. 14 are each 400 μm.

In order to vary the resistance of the polarization electrode, a heater 133 is provided, for example, within the insulating layer 34. The heater 133 is connected to the heater driver 132 illustrated in FIG. 11 through a wire 111g. When it is desired that the polarization amount of the piezoelectric bodies 11a to 11e be increased, a current is applied to the heater 133 to increase the temperature to a level at which the polarization electrodes are electrically conductive. The heater includes a thin layer pattern made of, for example, nickel chromium (NiCr) or tungsten (W). In addition, another heater (not illustrated) may be provided within the insulating layer 35. Preferably, the polarization electrodes are made of a material having an electric conductivity at temperatures close to the Curie temperature of the piezoelectric body. Since thermal fluctuations of electrons and electric dipoles are more increased at temperatures close to the Curie temperature of the piezoelectric body than at room temperature, the piezoelectric body can be more easily polarized.

While the piezoelectric actuator of the present invention includes a plurality of piezoelectric elements arranged in an array, the head slider of the present invention can include at least one piezoelectric element. The piezoelectric actuator in which a plurality of piezoelectric elements are arranged in an array with one of each pair of polarization electrodes in contact with the substrate, as in the present embodiment, has a higher power than a piezoelectric actuator defined by a single piezoelectric element. Since such a piezoelectric actuator contributes to the high-speed control of the flying height D2, a head slider includes a piezoelectric actuator including a plurality of piezoelectric elements is preferred.

When the head slider 105 is attached to the magnetic head support and the magnetic disk, in general, it is disposed in such a manner that the slider substrate 105a is located at the air intake side and the magnetic head 105b is located at the air discharge side.

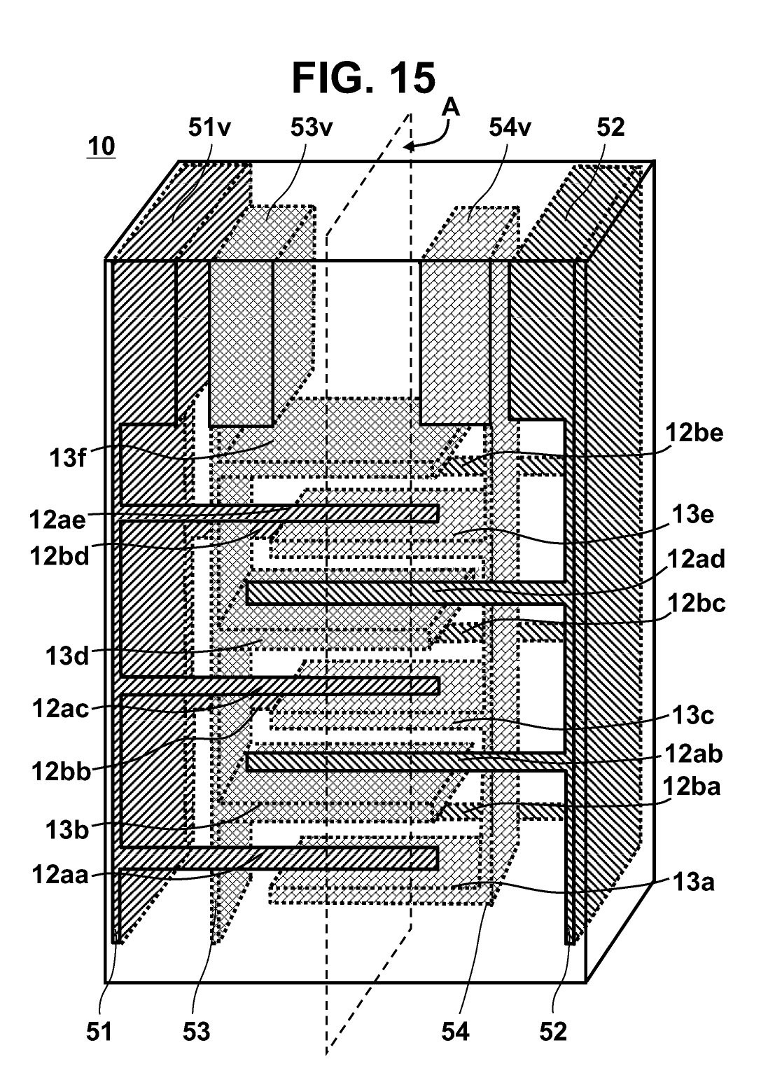

FIG. 15 is a perspective view of the head slider, illustrating only the electrodes of the piezoelectric actuator. The driving electrodes 13a, 13c and 13e are connected to a base electrode 53. The driving electrodes 13b, 13d and 13f are connected to a base electrode 54. The polarization electrodes 12aa, 12bb, 12ac, 12bd and 12ae are connected to a base electrode 51. The polarization electrodes 12ab, 12ba, 12bc, 12ad and 12be are connected to a base electrode 52. The base electrodes 51, 52, 53 and 54 are electrically connected to voltage supply terminals 51v, 52v, 53v and 54v, respectively. The voltage supply terminals 51v, 52v, 53v and 54v are connected to the external terminals 41t, 42t, 43t and 44t illustrated in FIG. 13, respectively. The materials of the base electrodes and the voltage supply terminals are not particularly limited as long as they are electrically conductive. For example, electroconductive materials, such as copper (Cu), gold (Au), platinum (Pt) and iridium (Ir), can be used. Among those, preferred are copper (Cu) and gold (Au) because of ease of plating. Section A illustrated in FIG. 15 corresponds to the section illustrated in FIG. 14.

A potential from the control circuit unit 110 is applied to the piezoelectric elements (not illustrated) through the external terminals 41t to 44t and the voltage supply terminals 51v to 54v. When, for example, it is desired that the piezoelectric bodies 11a to 11e be polarized as illustrated in FIG. 14, potentials are respectively applied to the base electrode 51 and the base electrode 52 so that the base electrode 51 has a lower potential than the base electrode 52 at a temperature at which the polarization electrodes 12aa to 12ae and 12ba to 12be become electrically conductive. When, for example, electric fields are applied for driving the piezoelectric bodies 11a to 11e as illustrated in FIG. 14, potentials are respectively applied to the base electrode 53 and the base electrode 54 so that the base electrode 53 has a lower potential than the base electrode 54 at a temperature at which the polarization electrodes 12aa to 12ae and 12ba to 12be become electrically isolated. By applying such electric fields, all the piezoelectric elements 10a to 10e are deformed in the same direction. The displacements (sharing displacements) of the piezoelectric elements 10a to 10e are in the d₁₅ mode. In order that the electric fields applied to the piezoelectric bodies act effectively to cause deformation in such direction reliably, it is preferable that the direction (first direction) from one of the two polarization electrodes with the piezoelectric body therebetween toward the other be perpendicular to the direction (second direction) from one of the two driving electrodes with the piezoelectric body therebetween toward the other. It is also preferable that the second direction be parallel to the normal to the flying surface 105f of the head slider 105.

The d₁₅ sharing strain provides a higher piezoelectric constant than the d₃₁ or d₃₃ strain, and its strain amount is larger. The d₁₅ shearing strain has an aspect ratio dependence. By increasing the aspect ratio, a large displacement can be produced in the direction in which the flying height of the magnetic head 105h varies.

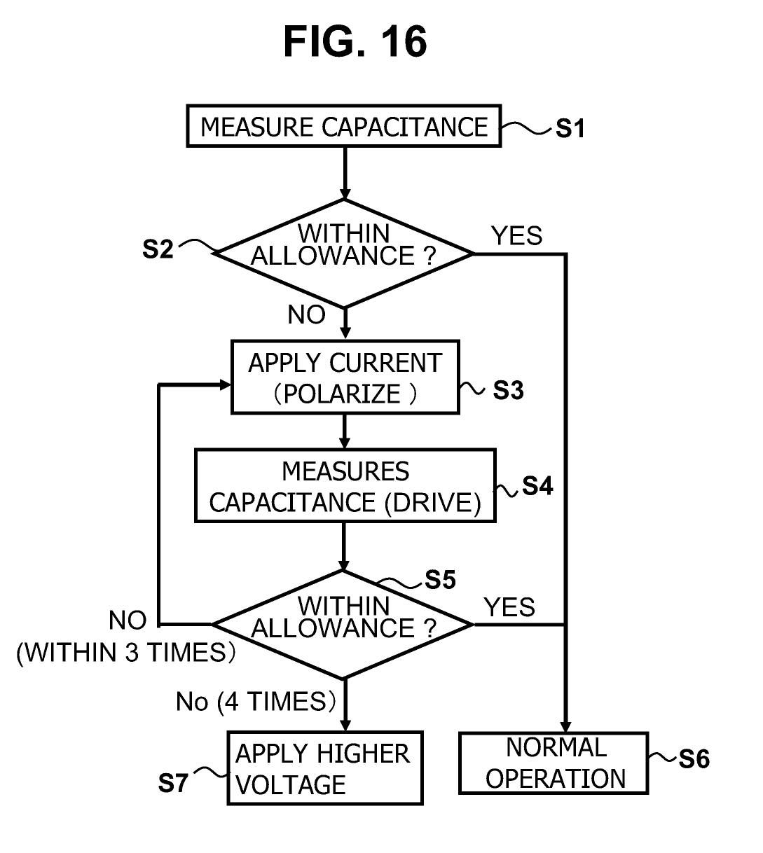

FIG. 16 is a flow chart of a control means for recovering the displacement of the piezoelectric actuator in a magnetic disk drive according to the above embodiment by increasing the polarization amount of the piezoelectric body.

First, the CPU 112 measures the capacitance of the piezoelectric bodies 11a to 11e (S1). The degree of the polarization of the piezoelectric bodies 11a to 11e can be known by measuring the capacitance. A capacitance measuring unit 113 is connected to the polarization electrodes 12aa to 12ae and 12ba to 12be and the driving electrodes 13a to 13f through a wire 111e so that the capacitances between the polarization electrodes and the capacitances between the driving electrodes, of the respective piezoelectric bodies 11a to 11e can be measured. The CPU 112 operates the capacitance measuring unit 113 to measure the capacitances of the respective piezoelectric bodies 11a to 11e between the polarization electrodes and between the driving electrodes. The measured capacitances are temporarily stored in the RAM 114.

Then, the CPU 112 compares the measured capacitances of the piezoelectric bodies 11a to 11e with a reference value previously stored in the ROM 115 (S2). More specifically, the CPU 112 compares the measurement results of capacitance temporarily stored in the RAM 114 with reference values of the capacitances of the piezoelectric bodies 11a and 11e between the polarization electrodes and between the driving electrodes, stored in the ROM 115. The reference values of the capacitances can appropriately be set, and may be set within the initial capacitance ±10%.

If both the capacitances of the piezoelectric bodies between the polarization electrodes and between the driving electrodes 11a to 11e are each within a predetermined range of the corresponding reference value, the polarization amounts of the piezoelectric bodies 11a to 11e may not be increased, and normal operation is performed afterward (S6). For example, the CPU 112 performs recording and writing while operating the actuator controller 116 and the actuator driver 118 to control the flying height.

If either the capacitance between the polarization electrodes or the capacitance between the driving electrodes, of the piezoelectric bodies 11a to 11 is lower than the previously set corresponding reference value, the CPU 112 polarizes the piezoelectric bodies 11a and 11e (S3). More specifically, for example, the CPU 112 operates the heater controller 131 and the heater driver 132 to apply a current to the heater 133, thereby heating the actuator 10, and further operates the actuator controller 116 and the actuator driver 118 to apply predetermined potentials to the respective polarization electrodes. For example, 0 V is applied to the polarization electrodes 12aa, 12bb, 12ac, 12bd and 12ae, and 100 V is applied to the polarization electrodes 12ba, 12ab, 12bc, 12ad, and 12be.

Then, the CPU 112 measures the capacitance of the piezoelectric bodies 11a to 11e (S4). This measurement is performed in the same manner as in S1. Then, the CPU 112 compares the measured capacitances of the piezoelectric bodies 11a to 11e with reference values previously stored in the ROM 115 (S5). This comparison is performed in the same manner as in S2. If both the capacitances of the piezoelectric bodies 11a to 11e between the polarization electrodes and between the driving electrodes are predetermined respective reference values or more, the polarization amounts of the piezoelectric bodies 11a to 11e may not be increased, and normal operation is performed afterward (S6). If either the capacitance between the polarization electrodes or the capacitance between the driving electrodes, of the piezoelectric bodies 11a to 11 is lower than the previously set corresponding reference value, the process step returns to S3 and CPU 112 polarizes the piezoelectric bodies 11a and 11e.

If either the capacitance between the polarization electrodes or the capacitance between the driving electrodes, of the piezoelectric bodies 11a to 11e is lower than the previously set corresponding reference value even though the polarization is performed three times, the CPU 112 performs recording and reproduction while controlling the flying height by operating the actuator controller 116 and the actuator driver 118 so that a higher voltage is applied between the driving electrodes (S7).

—Process for Manufacturing the Head Slider—

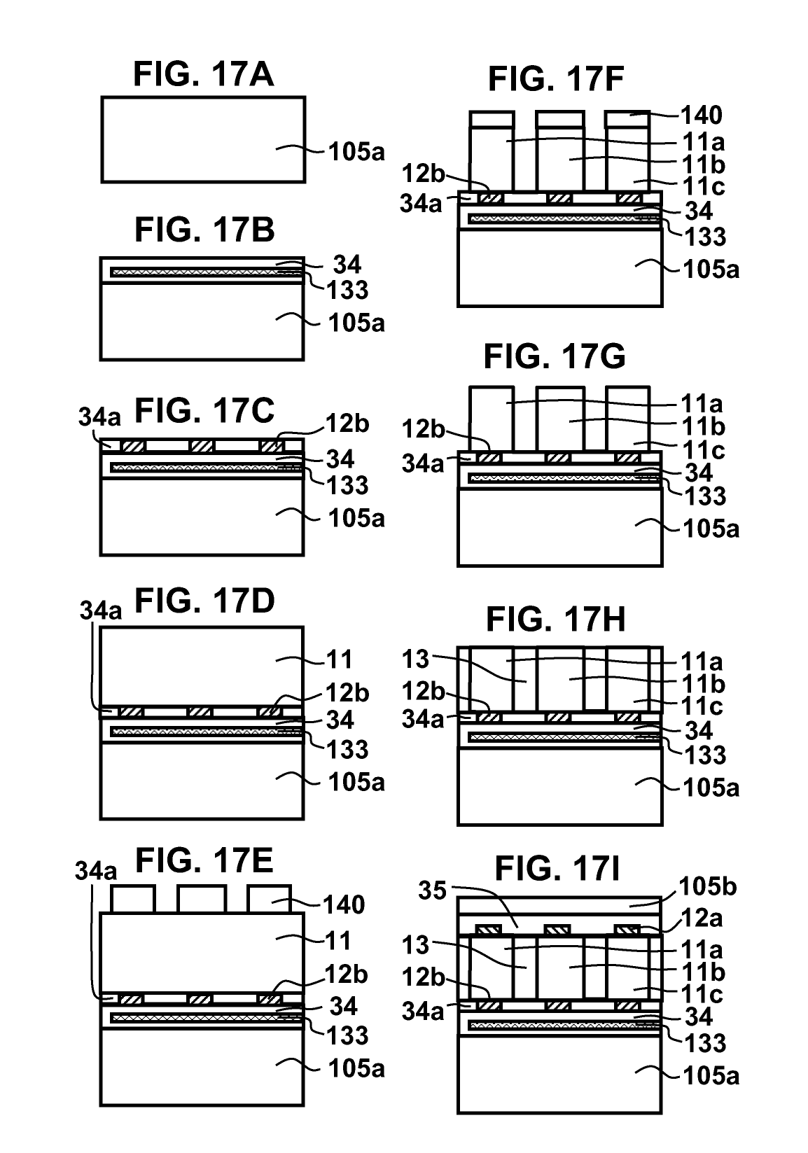

A process for manufacturing the head slider 105 illustrated in FIGS. 13 to 15 will now be described with reference to FIGS. 17A to 17I. FIGS. 17A to 17I illustrate only 10a to 10c of the piezoelectric elements 10a to 10e. The polarization electrodes 12aa to 12ae are collectively called the polarization electrodes 12a; the polarization electrodes 12ba to 12be are collectively called the polarization electrodes 12b; and the driving electrodes 13a to 13f are collectively called the driving electrodes 13.

First, for example, an AlTiC (Al₂O₃—TiC) wafer substrate is prepared as the slider substrate 105a (FIG. 17A).

Subsequently, for example, alumina (Al₂O₃), titanium oxide (TiO₂) or the like is deposited to a thickness of about 250 nm on the surface of the slider substrate 105a by sputtering. Then, a film of nickel chromium (NiCr), tungsten (W) or the like is deposited to a thickness of 200 nm by sputtering or vacuum vapor deposition, and the deposited film is patterned into a heater 133 by photolithography and dry etching. Alumina (Al₂O₃), titanium oxide (TiO₂) or the like is further deposited to a thickness of about 250 nm so as to cover the heater 133, thus forming an insulating layer 34 in which the heater 133 is embedded (FIG. 17B).

Then, the polarization electrodes 12b are formed on the insulating layer 34 by patterning. More specifically, for example, a SiC film is deposited to a thickness of about 200 nm by CVD. Subsequently, a resist layer pattern is formed corresponding to the shape of the desired polarization electrodes 12b, and the SiC film is patterned into a desired shape by dry etching. The resist pattern is then removed. Then, an insulating layer 34a of alumina (Al₂O₃), titanium oxide (TiO₂) or the like is deposited to cover the patterned polarization electrodes 12b, and the upper surface of the insulating layer is polished by CMP to expose the upper surface of the SiC film (FIG. 17C).

Next, as illustrated in FIG. 8, a piezoelectric body 11 mainly containing or made of a piezoelectric material, such as lead zirconate titanate (Pb(Zr,Ti)O₃: PZT) is formed so as to cover the polarization electrodes 12b (FIG. 17D). More specifically, PZT is deposited so as to cover the polarization electrodes 12b by sputtering, thus forming the piezoelectric body 11 having a thickness of about 5 μm. In this instance, for example, sol-gel method, pulsed laser vapor deposition, MOCVD, aerosol deposition and the like may be applied instead of sputtering.

Subsequently, a resist layer pattern 140 used for shaping the piezoelectric body 11 is formed on the piezoelectric body 11 (FIG. 17E). More specifically, for example, a resist layer is formed so that the width (in the direction perpendicular to the deposition direction) and the depth (in the direction perpendicular to the sheet of the figure) of the piezoelectric body 11 can have desired shapes in a subsequent dry etching step.

The piezoelectric body 11 is subjected to dry etching using the resist layer pattern 140 as a mask by inductively coupled plasma (ICP) using a fluorine-based or a chlorine-based gas. After the shaping by dry etching, the piezoelectric body 11 is subjected to annealing, for example, at 600° C. for 30 minutes in an oxygen atmosphere. Thus, the piezoelectric bodies 11a to 11e having a height (length in the deposition direction) of 3 μm, a width (perpendicular to the deposition direction) of 2 μm, and a depth (in the direction of the normal to the sheet of the figure) of 5 μm are formed by dry etching (FIG. 17F).

The resist layer pattern 140 is then removed (FIG. 17G).

Then, for example, a Cu/Cr plating seed layer is formed in grooves between the piezoelectric bodies 11a to 11e by sputtering, thus filling the grooves between the active portions with Cu by Cu plating. After filling with Cu, the surface polishing is performed by CMP to expose the tops of the piezoelectric bodies 11a to 11e, and thus the driving electrodes 13 are formed (FIG. 17H). The driving electrode 13 has, for example, a width (perpendicular to the deposition direction) of 1 μm, a depth (in the direction of the normal to the sheet of the figure) of 5 μm, and a height (length in the deposition direction) of 3 μm. In this step, the not illustrated base electrodes 51, 52, 53 and 54 and voltage supply terminals 51v, 52v, 53v and 54v are formed as well.

The polarization electrodes 12a are formed on the tops of the exposed piezoelectric bodies 11a to 11e. The polarization electrodes 12a are formed in the same step as the polarization electrodes 12b. Preferably, the polarization electrodes 12a and 12b are made of a material difficult to deform at about 300° C., such as silicon carbide (SiC), an metal oxide of manganese (Mn), cobalt (Co), nickel (Ni) or iron (Fe), or barium titanate (BaTiO₃) containing yttrium Y or La, because the step of heating to generally about 300° C. is performed in the subsequent step of forming a magnetic head 105b. Then, an insulating layer 35 is formed to a thickness of about 500 nm so as to cover the polarization electrodes 12a. The insulating layer 35 is formed in the same step as the insulating layer 34. Finally, the magnetic head 105b is formed (FIG. 171). Since the method for forming the magnetic head 105 is not directly involved in the present invention and the magnetic head can be formed by a general means, the description of the magnetic head will be omitted. When the insulating layer 35 and the magnetic head 105 are formed, the external terminals 41t, 42t, 43t, and 44t (not illustrated) are also formed. In the process for forming the external terminals, for example, a resist pattern is formed after the insulating layer and the magnetic head 105b are formed, subsequently portions corresponding to the external terminals are removed by dry etching, and then external terminals are formed by plating.

Finally, the AlTiC wafer substrate 105a on which each layer has been formed is cut into head sliders 105 with a dicing saw. The head slider 105 is completed by the above-described manufacturing method. The cut head slider 105 is bonded to the gimbal 106g of the suspension 106, for example, with an adhesive.

Although a head slider and a magnetic disk drive have been described as applications of the piezoelectric actuator according to the embodiments of the invention, the piezoelectric actuator of the above embodiments can be used in other application, for example, for controlling the discharge of ink from an ink jet printer.

The piezoelectric actuator of the present invention can increase the polarization amount of the piezoelectric body to recover the displacement.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present inventions have been described in detail, it should be understood that the various changes, substitutions, and alterations could be made hereto without departing from the spirit and scope of the invention.

What is claimed is:

1. A piezoelectric actuator comprising:
a piezoelectric body;
a first and a second electrode for applying an electric field to the piezoelectric body in order to polarize the piezoelectric body in a first direction at an elevated temperature, at least one of the first and the second electrode including a material whose resistivity decreases with elevation of the temperature; and
a third and a fourth electrode for applying an electric field to the piezoelectric body in a second direction across the first direction of the polarization of the piezoelectric body in order to actuate the piezoelectric body.

2. The piezoelectric actuator according to claim 1, wherein the second direction is perpendicular to the first direction.

3. The piezoelectric actuator according to claim 1, wherein the material of the at least one of the first and the second electrode having a resistance of 1 MΩ or more at an operating temperature.

4. The piezoelectric actuator according to claim 3, wherein the material of the at least one of the first and the second electrode has the electric insulation at the operating temperature.

5. The piezoelectric actuator according to claim 1, further comprising a heater for heating the at least one of the first and the second electrode.

6. The piezoelectric actuator according to claim 1, wherein the piezoelectric body is interposed between the first and the second electrode.

7. The piezoelectric actuator according to claim 1, wherein the electric field applied by the third and the fourth electrode causes a shearing strain which generates a displacement of the piezoelectric body.

8. The piezoelectric actuator according to claim 1, wherein the piezoelectric body is interposed between the third and the fourth electrode, further comprising:
another piezoelectric body disposed opposite to the piezoelectric body with the fourth electrode therebetween;
another first and another second electrode for applying an electric field to the another piezoelectric body in order to polarize the piezoelectric body in a third direction opposite to the first direction of the polarization of the piezoelectric body, at least one of the first and the second electrode including a material whose resistivity decreases with elevation of the temperature; and
a fifth electrode disposed opposite to the fourth electrode with the another piezoelectric body therebetween, the fourth and the fifth electrode being capable of applying an electric field to the another piezoelectric body in order to polarize the piezoelectric body in a fourth direction across the third direction of the polarization of the another piezoelectric body.

9. A head slider comprising:
a slider substrate;
a piezoelectric actuator on the slider substrate, including:
a piezoelectric body,
a first and a second electrode, for applying an electric field to the piezoelectric body in order to polarize the piezoelectric body in a first direction at an elevated temperature, at least one of the first and the second electrode including a material whose resistivity decreases with elevation of the temperature, and
a third and a fourth electrode, for applying an electric field to the piezoelectric body in a second direction acrossing the first direction of the polarization of the piezoelectric body in order to actuate the piezoelectric body;
a magnetic head on the piezoelectric actuator; and
a heater for heating the at least one of the first and the second electrode.

10. The head slider according to claim 9, wherein the first direction is parallel to a direction from the slider substrate to the magnetic head.

11. The head slider according to claim 9, wherein the second direction is perpendicular to the first direction.

12. The head slider according to claim 9, wherein the material of the at least one of the first and the second electrode having an electric insulation at an operating temperature.

13. The head slider according to claim 9, wherein the electric field applied by the third and the fourth electrode causes a shearing strain which generates a displacement of the piezoelectric body, the displacement causing a displacement of the magnetic head in a direction perpendicular to a direction from the slider substrate to the magnetic head.

14. The head slider according to claim 10, wherein the piezoelectric body is interposed between the third and the fourth electrode, further comprising:
another piezoelectric body disposed opposite to the piezoelectric body with the fourth electrode therebetween;
another first and another second electrode for applying an electric field to the another piezoelectric body in order to polarize the piezoelectric body in a third direction opposite to the first direction of the polarization of the piezoelectric body, at least one of the first and the second electrode including a material whose resistivity decreases with elevation of the temperature; and
a fifth electrode disposed opposite to the fourth electrode with the another piezoelectric body therebetween, the fourth and the fifth electrode being capable of applying an electric field to the another piezoelectric body in order to polarize the piezoelectric body in a fouth direction across the third direction of the polarization of the another piezoelectric body.

15. A magnetic disk drive comprising:
a storage disk for storing information; and
a head slider including:
a slider substrate;
a piezoelectric actuator on the slider substrate, including:
a piezoelectric body,
a first and a second electrode, for applying an electric field to the piezoelectric body in order to polarize the piezoelectric body in a first direction at an elevated temperature, at least one of the first and the second electrode including a material whose resistivity decreases with elevation of the temperature, and
a third and a fourth electrode, for applying an electric field to the piezoelectric body in a second direction acrossing the first direction of the polarization of the piezoelectric body in order to actuate the piezoelectric body;
a magnetic head on the piezoelectric actuator, for storing information on the storage disk; and
a heater for heating the at least one of the first and the second electrode.

16. The magnetic disk drive according to claim 15, further comprising:
a capacitance measuring unit for measuring the capacitance of the piezoelectric body; and
a controller for comparing the capacitances of the piezoelectric bodies measured by the capacitance measuring unit with a predetermined capacitance, the controller applying an electric field between the first electrode and the second electrode in accordance with a result obtained from the comparing by the controller.

17. The magnetic disk drive according to claim 16, wherein the capacitance measuring unit is connected to the first and the second electrode.

18. The magnetic disk drive according to claim 16, wherein the capacitance measuring unit is connected to the third and the fourth electrode.
